(19) United States
(12) Patent Application Publication
(10) Pub. No.: US 2024/0179834 A1
(43) Pub. Date: May 30, 2024

(54) DECORATIVE FLEXIBLE-ELECTRONIC-FILM STRUCTURE AND METHOD OF FORMING THE SAME

(71) Applicant: DARWIN PRECISIONS CORPORATION, Hsinchu County (TW)

(72) Inventors: Hsuan Yao, Hsinchu County (TW); Yi Feng Chen, Hsinchu County (TW); Chia Tsun Huang, Hsinchu County (TW); Keng-Kuei Liang, Hsinchu County (TW)

(21) Appl. No.: 18/126,483

(22) Filed: Mar. 27, 2023

(30) Foreign Application Priority Data
Nov. 29, 2022 (TW) 111145556

(51) Int. Cl. H05K 1/02; B29C 45/00; B29C 51/44

(52) U.S. Cl. CPC H05K 1/028; B29C 45/0001; B29C 51/44; H05K 1/0237; H05K 1/0296; H05K 2201/09063; H05K 2201/10106; H05K 2201/10393

(57) ABSTRACT

A decorative flexible-electronic-film structure includes a mechanical member and a flexible electronic molded film. The mechanical member includes a mainboard part and a curved clamping part, and an accommodating slot is formed on the mainboard part. The flexible electronic molded film includes a body part, a side hook part and an electronic component, an inner surface of the body part faces the mainboard part, the electronic component is disposed on the inner surface and corresponds to the accommodating slot, and the side hook part is formed on the periphery of the body part and is curved. The flexible electronic molded film is assembled onto the mechanical member, with the body part overlapping the mainboard part, the electronic component being accommodated in the accommodating slot, and the side hook part being buckled to the clamping part. A method of forming the decorative flexible-electronic-film structure is also provided.

### FIELD OF THE INVENTION

The present invention relates to a film structure, and more particularly to a decorative flexible-electronic-film structure formed by combining a flexible electronic molded film having an exterior decoration function with a mechanical member, and a method of forming the same.

### BACKGROUND OF THE INVENTION

At present, one way to combine a flexible electronic molded film with a mechanical member is to first combine a flexible printed circuit (FPC) with the mechanical member through back glue, and then carry out exterior decoration through an in-mold decoration (IMD) molding process. A light-emitting diode (LED) is disposed on the flexible printed circuit, and an LED lens needs to be installed on the mechanical member so as to export an LED light source. Therefore, the process is complicated, and low yields and high costs may be caused.

Another way to combine the flexible electronic molded film with the mechanical member is to directly combine flexible electronics with the mechanical member based on in-mold electronics (IME) technology. Although the mechanical design may be simplified by this way (e.g., omitting the LED lens), the in-mold electronics technology has technical difficulties during in-mold molding, such as punching, plastic ink-charging, plastic punching deviation of electronic components, and in-mold positioning. The process is complicated, and low yields and high costs may be caused.

### SUMMARY OF THE INVENTION

The present invention provides a decorative flexible-electronic-film structure and a method of forming the same, and has the advantages of simplifying processes to reduce costs and decentralizing the processes to improve yields.

A decorative flexible-electronic-film structure according to the present invention includes a mechanical member and a flexible electronic molded film. The mechanical member includes a mainboard part and a clamping part, the mainboard part has an outer side surface and an inner side surface opposite to each other, the clamping part is formed on the periphery of the mainboard part and is curved toward the inner side surface, and an accommodating slot is provided in the outer side surface. The flexible electronic molded film includes a body part, a side hook part and electronic component, the body part has an inner surface and an exterior surface, the inner surface and the exterior surface are opposite, the inner surface faces the outer side surface, the electronic component is disposed on the inner surface and corresponds to the accommodating slot, and the side hook part is formed on the periphery of the body part and is curved toward the inner surface. The flexible electronic molded film is suitable for being assembled onto the mechanical member, with the body part overlapping the mainboard part, the electronic component being accommodated in the accommodating slot, and the side hook part being buckled to the clamping part.

According to one embodiment of the present invention, thicknesses of the body part and the side hook part of the flexible electronic molded film are smaller than a thickness of the mechanical member.

According to one embodiment of the present invention, a clamping hook is provided at an edge, away from the body part, of the side hook part, and the clamping hook interferes with an edge, away from the mainboard part, of the clamping part.

According to one embodiment of the present invention, the mechanical member is a plastic injected member, and the body part and the side hook part of the flexible electronic molded film are a blister molded member.

According to one embodiment of the present invention, the electronic component includes a light-emitting diode.

According to one embodiment of the present invention, the flexible electronic molded film further includes a conductive line formed on the inner surface of the body part, the conductive line is electrically connected to the electronic component, and a hollowed-out region is formed in the mainboard part of the mechanical member to expose part of the conductive line.

According to one embodiment of the present invention, the flexible electronic molded film further includes a microcontroller disposed on the inner surface of the body part and electrically connected to the conductive line.

According to one embodiment of the present invention, the decorative flexible-electronic-film structure further includes a signal transmission component disposed on a side, away from the body part, of the mainboard part, part of the signal transmission component penetrating through the hollowed-out region to be electrically connected to the conductive line.

According to one embodiment of the present invention, the signal transmission component is one or a combination of a flexible printed circuit and a flexible flat cable.

According to one embodiment of the present invention, the flexible electronic molded film further includes an exterior printed layer disposed on at least one of the inner surface and the exterior surface.

A method of forming a decorative flexible-electronic-film structure according to the present invention includes: providing a mechanical member, the mechanical member including a mainboard part and a clamping part, the mainboard part having an outer side surface and an inner side surface opposite to each other, the clamping part being formed on the periphery of the mainboard part and being curved toward the inner side surface, an accommodating slot being provided in the outer side surface; providing a flexible electronic molded film, the flexible electronic molded film including a body part, a side hook part and an electronic component, the body part having an inner surface and an exterior surface, the inner surface and the exterior surface being opposite, the inner surface facing the outer side surface, the electronic component being disposed on the inner surface and corresponding to the accommodating slot, the side hook part being formed on the periphery of the body part and being curved toward the inner surface; and assembling the flexible electronic molded film onto the mechanical member, with the body part overlapping the mainboard part, the electronic component being accommodated in the accommodating slot, and the side hook part being buckled to the clamping part.

According to one embodiment of the present invention, the body part and the side hook part of the flexible electronic molded film are molded by a blister molding process.

According to one embodiment of the present invention, the mechanical member is molded by a plastic injection process.

According to one embodiment of the present invention, a clamping hook is provided at an edge, away from the body part, of the side hook part, and when the flexible electronic molded film is assembled onto the mechanical member, the clamping hook interferes with an edge, away from the mainboard part, of the clamping part.

According to one embodiment of the present invention, before the flexible electronic molded film is assembled onto the mechanical member, a conductive line is formed on the inner surface of the body part of the flexible electronic molded film, and then the electronic component is set to be electrically connected to the conductive line.

According to one embodiment of the present invention, the method further includes: providing a signal transmission component on a side, away from the body part, of the mainboard part, a hollowed-out region being formed in the mainboard part to expose part of the conductive line, part of the signal transmission component penetrating through the hollowed-out region to be electrically connected to the conductive line.

According to one embodiment of the present invention, before the flexible electronic molded film is assembled onto the mechanical member, an exterior printed layer is formed on at least one of the inner surface and the exterior surface of the body part of the flexible electronic molded film.

According to the present invention, the flexible electronic molded film and the mechanical member are produced separately and assembled in a buckled manner which is simple and fast, such that the processes can be simplified to reduce the costs; and by decentralizing the processes of the flexible electronic molded film and the mechanical member, defective products may be rejected in advance, the risk that a whole batch of decorative flexible-electronic-film structures are poor and scrapped is avoided, and thus yields are improved.

In order to make the above and other objectives, features and advantages of the present invention more clearly understood, embodiments are described below in detail in conjunction with the accompanying drawings.

### BRIEF DESCRIPTION OF THE DRAWINGS

The present invention will become more readily apparent to those ordinarily skilled in the art after reviewing the following detailed description and accompanying drawings, in which:

FIG. 1 illustrates an exploded view of a decorative flexible-electronic-film structure according to an embodiment of the present invention;

FIG. 2 illustrates an assembly view of a decorative flexible-electronic-film structure according to an embodiment of the present invention;

FIG. 3 illustrates a three-dimensional sectional view of a decorative flexible-electronic-film structure according to an embodiment of the present invention; and

FIG. 4A to FIG. 4D illustrate sectional views of a method of forming a decorative flexible-electronic-film structure according to an embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

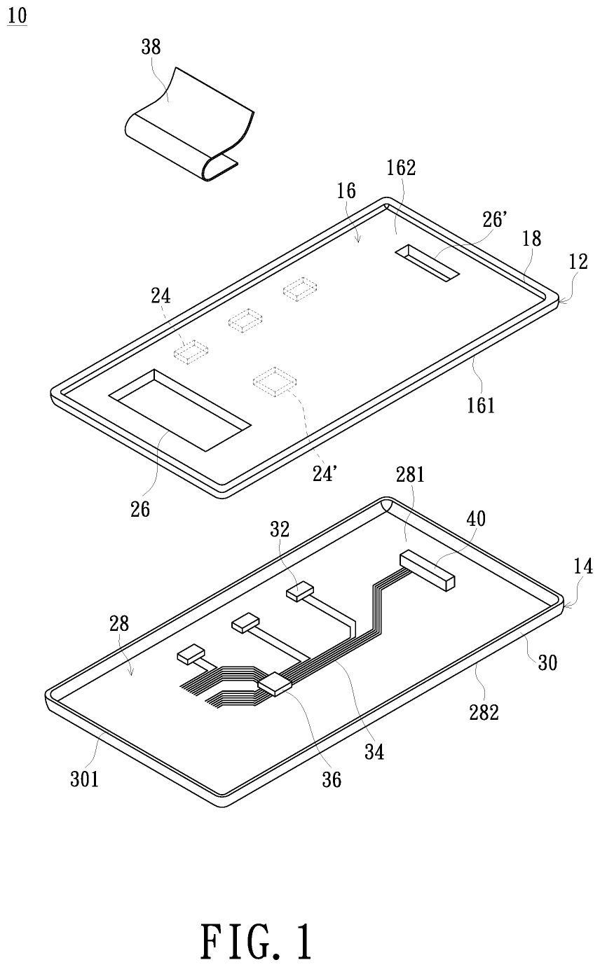

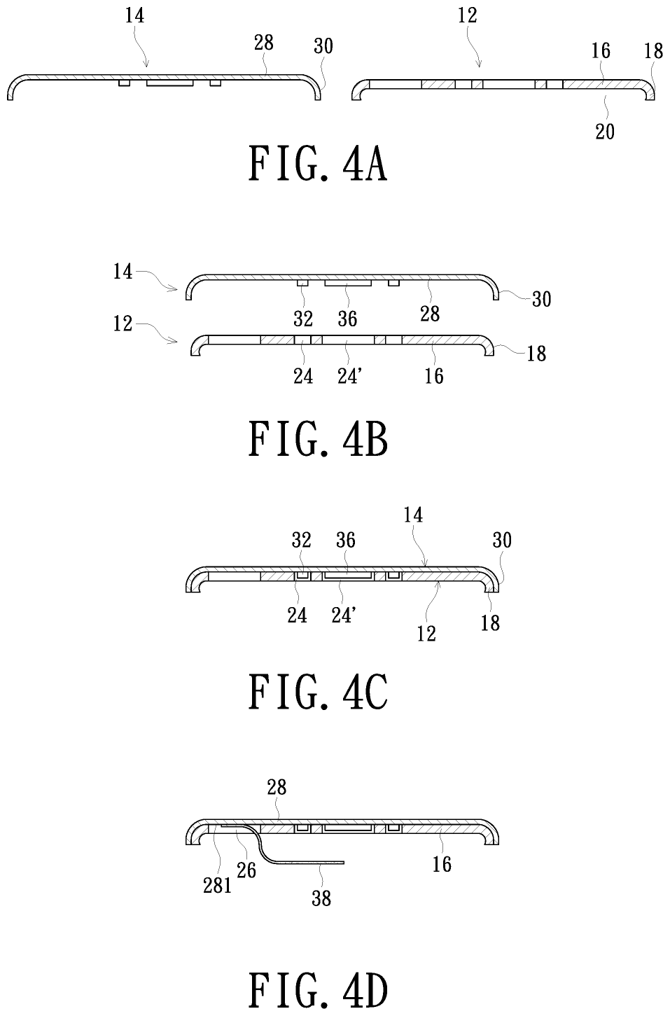

FIG. 1 illustrates an exploded view of a decorative flexible-electronic-film structure according to an embodiment of the present invention. As shown in FIG. 1, the decorative flexible-electronic-film structure 10 includes a mechanical member 12 and a flexible electronic molded film 14. The mechanical member 12 includes a mainboard part 16 and a clamping part 18. The mainboard part 16 has an outer side surface 161 and an inner side surface 162 opposite to each other. The clamping part 18 is formed on the periphery of the mainboard part 16 and is curved toward the inner side surface 162. An accommodating space 20 (shown in FIG. 4A hereinafter) may be formed between the clamping part 18 and the inner side surface 162. Further, accommodating slots 24 are provided in the outer side surface 161. According to one embodiment, a hollowed-out region 26 is formed in the mainboard part 16. FIG. 1 illustrates an example that the mainboard part 16 is a rectangle and the clamping part 18 is located at four edges of the mainboard part 16. Further, the mainboard part 16 may also be round, oval and other shapes. According to one embodiment, the mechanical member 12 is a plastic injected member made of acrylonitrile-butadiene-styrene (ABS) plastic particles or polycarbonate (PC) plastic particles. Further, the mechanical member 12 may also be an iron member.

Continuing with the above description, the flexible electronic molded film 14 includes a body part 28, a side hook part 30, and electronic components 32. The body part 28 has an inner surface 281 and an exterior surface 282. The inner surface 281 and the exterior surface 282 are opposite. The inner surface 281 faces the outer side surface 161 of the mainboard part 16 of the mechanical member 12. The electronic components 32 are disposed on the inner surface 281 and correspond to the accommodating slots 24 in the mainboard part 16. The side hook part 30 is formed on the periphery of the body part 28 and is curved toward the inner surface 281. According to one embodiment, a clamping hook 301 is formed at an edge, away from the body part 28, of the side hook part 30. FIG. 1 illustrates an example that the body part 28 is a rectangle and the side hook part 30 is located at four edges of the body part 28. Further, the body part 28, corresponding to the mainboard part 16 of the mechanical member 12, may also be round, oval and other shapes. According to one embodiment, the body part 28 and the side hook part 30 are a blister molded member. The body part 28 and the side hook part 30 are, for example, in the form of transparent film. The body part 28 and the side hook part 30 are, for example, made of an ABS sheet or PC sheet, and are subjected to blister molding to form the three-dimensional exterior of the flexible electronic molded film 14.

According to one embodiment, the electronic components 32 of the flexible electronic molded film 14 include, for example, light-emitting diodes (LEDs). Further, according to one embodiment, the flexible electronic molded film 14 may further include a conductive line 34 and a microcontroller 36. As shown in FIG. 1, the conductive line 34 is formed on the inner surface 281 of the body part 28, and the conductive line 34 may include, for example, positive and negative lines of the electronic component 32 (such as LEDs). The microcontroller 36 is disposed on the inner surface 281 of the body part 28, and the mainboard part 16 of the mechanical member 12 is also provided with an accommodating slot 24′ corresponding to the microcontroller 36. The conductive line 34 is electrically connected to the electronic components 32 and the microcontroller 36. The conductive line 34 is made of, for example, silver adhesive. According to one embodiment, the electronic components 32 (such as LEDs) and the microcontroller 36 may be disposed on the inner surface 281 of the body part 28 through, for example, a punching process.

The conductive line 34 may also include a touch circuit, such that the flexible electronic molded film 14 also has a touch function. According to one embodiment, the flexible electronic molded film 14 may further include an exterior printed layer (not shown). The exterior printed layer is provided on one or both of the inner surface 281 and the exterior surface 282. The exterior printed layer may, for example, have different plastic colors and surface patterns.

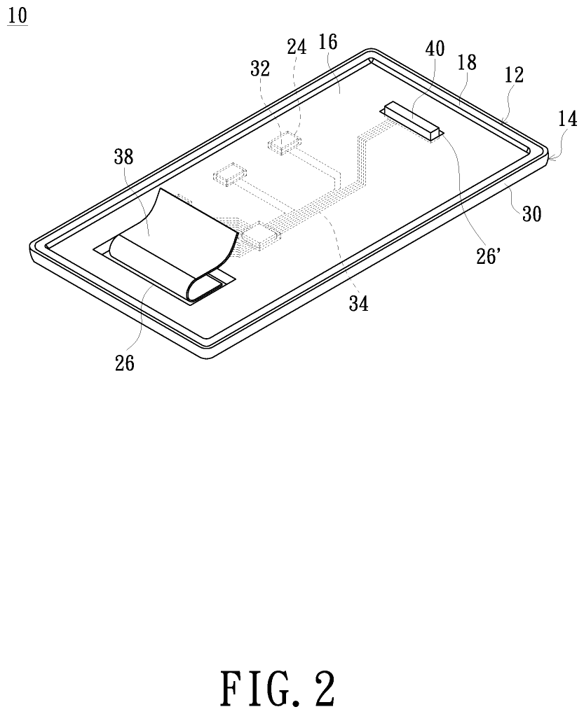

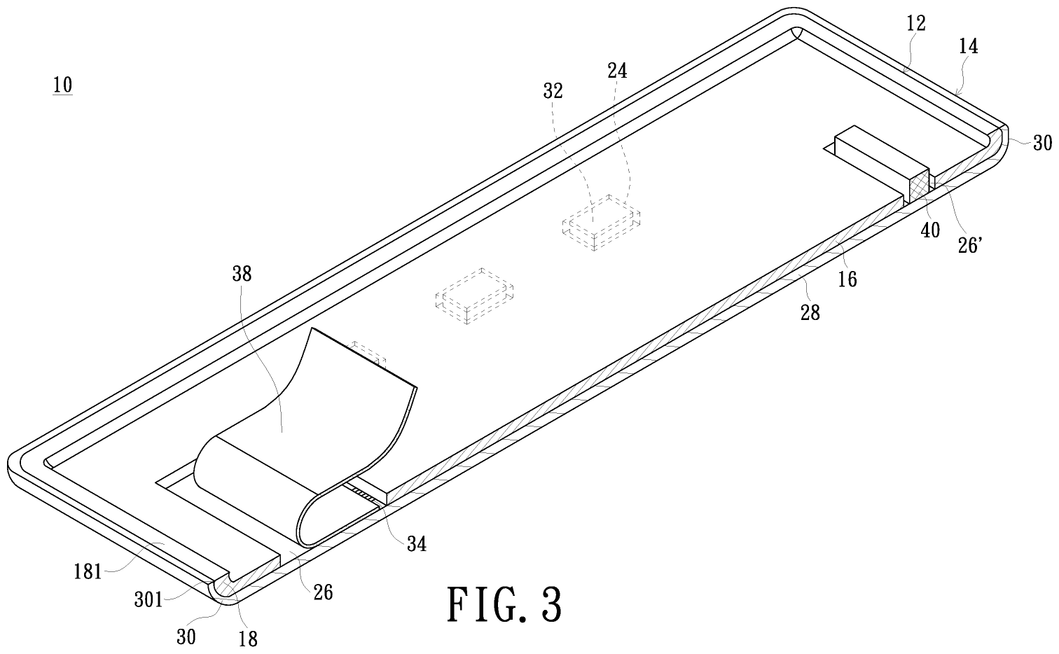

FIG. 2 illustrates an assembly view of the decorative flexible-electronic-film structure according to the embodiment of the present invention. FIG. 3 illustrates a three-dimensional sectional view of the decorative flexible-electronic-film structure according to the embodiment of the present invention. As shown in FIG. 2 and FIG. 3, the flexible electronic molded film 14 is suitable for being assembled onto the mechanical member 12, so that the flexible electronic molded film 14 partially covers the mechanical member 12, with the body part 28 of the flexible electronic molded film 14 overlapping the mainboard part 16 of the mechanical member 12, the electronic components 32 being accommodated in the accommodating slots 24, and the side hook part 30 being buckled to the clamping part 18. Further, the clamping hook 301 of the side hook part 30 interferes with an edge 181 of the clamping part 18. According to one embodiment, the thickness of the flexible electronic molded film 14 is smaller than the thickness of the mechanical member 12, and the side hook part 30 of the flexible electronic molded film 14 has a deformation space. When the flexible electronic molded film 14 is assembled onto the mechanical member 12, the side hook part 30 is first slightly expanded and then clamps and covers the clamping part 18, such that the flexible electronic molded film 14 and the mechanical member 12 are assembled. The conductive line 34 formed on the inner surface 281 (shown in FIG. 1) of the flexible electronic molded film 14 is partially exposed through the hollowed-out region 26 of the mechanical member 12.

Continuing with the above description, as shown in FIG. 1 to FIG. 3, the decorative flexible-electronic-film structure 10 according to the embodiment of the present invention further includes a signal transmission component 38 disposed on a side, away from the body part 28, of the mainboard part 16. As shown in FIG. 2 and FIG. 3, part of the signal transmission component 38 penetrates through the hollowed-out region 26 to be electrically connected to the conductive line 34. According to one embodiment, the signal transmission component 38 is one or a combination of a flexible printed circuit (FPC) and a flexible flat cable (FFC). Specifically, according to one embodiment, the signal transmission component 38 may be connected to the conductive line 34 through conductive adhesive (not shown). Alternatively, a connector component 40 may be provided on the flexible electronic molded film 14, and the connector component 40 is exposed through a hollowed-out region 26′ of the mechanical member 12. According to an unillustrated embodiment, the signal transmission component 38 may be electrically connected to the conductive line 34 via the connector component 40. An external electronic signal is provided to the conductive line 34 via the signal transmission component 38, such that the decorative flexible-electronic-film structure 10 according to the embodiment of the present invention may be connected to an external system device or an external component.

FIG. 4A to FIG. 4D illustrate sectional views of a method of forming a decorative flexible-electronic-film structure according to an embodiment of the present invention. As shown in FIG. 4A, a mechanical member 12 and a flexible electronic molded film 14 are formed by different processes. The structures of the mechanical member 12 and the flexible electronic molded film 14 are described according to the above embodiment and will thus not be repeated here. The mechanical member 12 is molded, for example, by a plastic injection process. A curved clamping part 18 is formed on the periphery of a mainboard part 16 of the mechanical member 12. A curved side hook part 30 is formed on the periphery of a body part 28 of the flexible electronic molded film 14. The body part 28 and the side hook part 30 are molded, for example, by a blister molding process. According to one embodiment, a conductive line 34 (shown in FIG. 1) and an exterior printed layer (not shown) may be produced before the body part 28, and then blister molding is carried out to form the three-dimensional exterior of the flexible electronic molded film 14.

Next, the mechanical member 12 and the flexible electronic molded film 14 produced separately are assembled. As shown in FIG. 4B, the body part 28 of the flexible electronic molded film 14 corresponds to the mainboard part 16 of the mechanical member 12, and the side hook part 30 of the flexible electronic molded film 14 corresponds to the clamping part 18 of the mechanical member 12. Then, the side hook part 30 and the clamping part 18 are buckled to assemble the flexible electronic molded film 14 and the mechanical member 12, as shown in FIG. 4C, where electronic components 32 (such as LEDs) and a microcontroller 36 of the flexible electronic molded film 14 are accommodated in accommodating slots 24 and an accommodating slot 24′ of the mechanical member 12 respectively.

Continuing with the above description, as shown in FIG. 4D, the method of forming the decorative flexible-electronic-film structure 10 further includes: a signal transmission component 38 is provided on one side, away from the body part 28, of the mainboard part 16. According to one embodiment, upon completion of the assembly of the mechanical member 12 and the flexible electronic molded film 14, one end of the signal transmission component 38 penetrates through a hollowed-out region 26 of the mechanical member 12, and is electrically connected to the conductive line 34 (shown in FIG. 1) on an inner surface 281 of the body part 28 through conductive adhesive (not shown). According to another unillustrated embodiment, the signal transmission component 38 may also be electrically connected to the conductive line via a connector component.

Therefore, in the method of forming the decorative flexible-electronic-film structure according to the embodiment of the present invention, the flexible electronic molded film and the mechanical member are produced separately and are assembled in a buckled manner which is simple and fast, such that the processes can be simplified to reduce the costs; and by decentralizing the processes of the flexible electronic molded film and the mechanical member, defective products can be rejected in advance, the risk that a whole batch of decorative flexible-electronic-film structures are poor and scrapped is avoided, and thus yields are improved. As the flexible electronic molded film has the exterior decoration function and the conductive line, and is provided with, for example, a light-emitting component, the decorative flexible-electronic-film structure obtained upon assembly of the flexible electronic molded film and the mechanical member has the functions of decoration, touch, light emitting and connection with an external system device.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A decorative flexible-electronic-film structure, comprising:
a mechanical member, comprising a mainboard part and a clamping part, the mainboard part having an outer side surface and an inner side surface opposite to each other, the clamping part being formed on the periphery of the mainboard part and being curved toward the inner side surface, at least one accommodating slot being provided in the outer side surface; and
a flexible electronic molded film, comprising a body part, a side hook part, and at least one electronic component, the body part having an inner surface and an exterior surface, the inner surface and the exterior surface being opposite, the inner surface facing the outer side surface, the at least one electronic component being disposed on the inner surface and corresponding to the at least one accommodating slot, the side hook part being formed on the periphery of the body part and being curved toward the inner surface, wherein the flexible electronic molded film is suitable for being assembled onto the mechanical member, with the body part overlapping the mainboard part, the at least one electronic component being accommodated in the at least one accommodating slot, and the side hook part being buckled to the clamping part.

2. The decorative flexible-electronic-film structure according to claim 1, wherein thicknesses of the body part and the side hook part of the flexible electronic molded film are smaller than a thickness of the mechanical member.

3. The decorative flexible-electronic-film structure according to claim 1, wherein a clamping hook is provided at an edge, away from the body part, of the side hook part, and the clamping hook interferes with an edge, away from the mainboard part, of the clamping part.

4. The decorative flexible-electronic-film structure according to claim 1, wherein the mechanical member is a plastic injected member, and the body part and the side hook part of the flexible electronic molded film are a blister molded member.

5. The decorative flexible-electronic-film structure according to claim 1, wherein the at least one electronic component comprises a light-emitting diode.

6. The decorative flexible-electronic-film structure according to claim 1, wherein the flexible electronic molded film further comprises a conductive line formed on the inner surface of the body part, the conductive line is electrically connected to the at least one electronic component, and a hollowed-out region is formed in the mainboard part of the mechanical member to expose part of the conductive line.

7. The decorative flexible-electronic-film structure according to claim 6, wherein the flexible electronic molded film further comprises a microcontroller disposed on the inner surface of the body part and electrically connected to the conductive line.

8. The decorative flexible-electronic-film structure according to claim 6, further comprising a signal transmission component disposed on a side, away from the body part, of the mainboard part, part of the signal transmission component penetrating through the hollowed-out region to be electrically connected to the conductive line.

9. The decorative flexible-electronic-film structure according to claim 8, wherein the signal transmission component is one or a combination of a flexible printed circuit and a flexible flat cable.

10. The decorative flexible-electronic-film structure according to claim 1, wherein the flexible electronic molded film further comprises an exterior printed layer disposed on at least one of the inner surface and the exterior surface.

11. A method of forming a decorative flexible-electronic-film structure, comprising:
providing a mechanical member, the mechanical member comprising a mainboard part and a clamping part, the mainboard part having an outer side surface and an inner side surface opposite to each other, the clamping part being formed on the periphery of the mainboard part and being curved toward the inner side surface, at least one accommodating slot being provided in the outer side surface;
providing a flexible electronic molded film, the flexible electronic molded film comprising a body part, a side hook part and at least one electronic component, the body part having an inner surface and an exterior surface, the inner surface and the exterior surface being opposite, the inner surface facing the outer side surface, the at least one electronic component being disposed on the inner surface and corresponding to the at least one accommodating slot, the side hook part being formed on the periphery of the body part and being curved toward the inner surface; and
assembling the flexible electronic molded film onto the mechanical member, with the body part overlapping the mainboard part, the at least one electronic component being accommodated in the at least one accommodating slot, and the side hook part being buckled to the clamping part.

12. The method of forming a decorative flexible-electronic-film structure according to claim 11, wherein the body part and the side hook part of the flexible electronic molded film are molded by a blister molding process.

13. The method of forming a decorative flexible-electronic-film structure according to claim 11, wherein the mechanical member is molded by a plastic injection process.

14. The method of forming a decorative flexible-electronic-film structure according to claim 11, wherein a clamping hook is provided at an edge, away from the body part, of the side hook part, and when the flexible electronic molded film is assembled onto the mechanical member, the clamping hook interferes with an edge, away from the mainboard part, of the clamping part.

15. The method of forming a decorative flexible-electronic-film structure according to claim 11, wherein before the flexible electronic molded film is assembled onto the mechanical member, a conductive line is formed on the inner surface of the body part of the flexible electronic molded film, and then the at least one electronic component is set to be electrically connected to the conductive line.

16. The method of forming a decorative flexible-electronic-film structure according to claim 11, further comprising: providing a signal transmission component on a side, away from the body part, of the mainboard part, a hollowed-out region being formed in the mainboard part to expose part of the conductive line, part of the signal transmission component penetrating through the hollowed-out region to be electrically connected to the conductive line.

17. The method of forming a decorative flexible-electronic-film structure according to claim 16, wherein the signal transmission component is one or a combination of a flexible printed circuit and a flexible flat cable.

18. The method of forming a decorative flexible-electronic-film structure according to claim 11, wherein before the flexible electronic molded film is assembled onto the mechanical member, an exterior printed layer is formed on at least one of the inner surface and the exterior surface of the body part of the flexible electronic molded film.
